(19) United States
(12) Patent Application Publication
(10) Pub. No.: US 2019/0300788 A1
(43) Pub. Date: Oct. 3, 2019

(54) RED NITRIDE PHOSPHOR AND LIGHT-EMITTING DEVICE USING THE SAME

(71) Applicant: BELL CERAMICS CO., LTD., New Taipei City (TW)

(72) Inventors: Shu-Yi MENG, Kaohsiung City (TW); Mu-Huai FANG, Taoyuan City (TW); Ru-Shi LIU, New Taipei City (TW); Chang-Lung CHIANG, New Taipei City (TW); Chang-Yang CHIANG, New Taipei City (TW); Te-Hsin CHIANG, New Taipei City (TW)

(21) Appl. No.: 16/025,944

(22) Filed: Jul. 2, 2018

Related U.S. Application Data
(60) Provisional application No. 62/648,877, filed on Mar. 27, 2018.

(51) Int. Cl. C09K 11/77; C09K 11/08; H01L 33/50; F21V 9/30

(52) U.S. Cl. CPC C09K 11/7734; C09K 11/0883; F21Y 2115/10; F21V 9/30; H01L 33/502

(57) ABSTRACT

A red nitride phosphor is provided. The red nitride phosphor is represented by the following general formula (I):

SrLi(GaₓAl₁₋ₓ)₃N₄:Eu²⁺ general formula (I),

in general formula (I), 0<x≤1.

### CLAIM FOR PRIORITY

This application claims the benefit of U.S. Provisional Patent Application No. 62/648,877 filed on Mar. 27, 2018, the subject matters of which are incorporated herein in their entirety by reference.

### BACKGROUND OF THE INVENTION

### Field of the Invention

The present invention provides a red nitride phosphor, especially a red nitride phosphor using Ga³⁺ as a dopant, and a light-emitting device using the red nitride phosphor.

### Descriptions of the Related Art

Phosphors are useful in light-emitting devices because of their high energy conversion characteristic. Examples of phosphors include oxide phosphors, nitride phosphors, nitrogen oxide phosphors and fluoride phosphors. These phosphors can be excited by a blue-light light-emitting diode and thus are widely used in backlight panels of various luminaires and displays. Among these phosphors, nitride phosphors are red phosphors that emit red light because they have lower electron negativity, i.e., stronger covalence, making the energy level of d-orbitals decreases due to the influence of Nephelauxetic Effect, and the electric charges of N³⁻ strengthen the crystal field effect, making the energy level gap between the 5d-orbital and the 4f-orbital decrease.

Backlight is a common illumination form used in display devices. The difference between backlight and front-light primarily lies in that backlight allows light to be emitted from the side or back of a display device and thus to increase illumination in a low light condition or enhance the brightness of the display device. Recently, light-emitting diodes have replaced cold cathode fluorescent lamps to be used as backlight source of back-lit displays. Light-emitting diodes can significantly lower the power dissipation and heat loss of displays and provide wider color gamut, and they are environmental friendly. Since a back-lit display may further comprise one or more filters to increase color purity and color rendering, fluorescents material should have suitable emission spectral position and full width at half maximum (FWHM) in order to decrease energy loss. Furthermore, fluorescents materials preferably have narrow emission spectra because there is a continuous need for displays with higher brightness and wider color gamut area, such as 4K displays and 8K displays, in the market.

Examples of conventional red nitride phosphors include (Sr,Ba)₂Si₅N₈:Eu²⁺ and (Ca,Sr)SiAlN₃:Eu²⁺, they both have good thermal stability. However, the emission spectra of (Sr,Ba)₂Si₅N₈:Eu²⁺ and (Ca,Sr)SiAlN₃:Eu²⁺ are broad, and a portion of the emission spectral position thereof is outside the sensitivity curve of human eyes. As a result, light-emitting devices using such phosphors have poor efficiency problem.

In 2014, Schnick et al. disclose in “Nature Materials, 2014, Vol. 13, p. 891-896” a new red nitride phosphor, i.e., SrLiAl₃N₄:Eu²⁺ (hereinafter “red nitride phosphor SLA”), which has a narrow emission spectrum. The red nitride phosphor SLA has a full width at half maximum (FWHM) of about 50 nm, an emission peak value of 650 nm, and good thermal stability due to rigid host lattice structure. According to the disclosure, the red nitride phosphor SLA can be obtained by reacting raw materials including LiAlH₄, AlN, SrH₂, and EuF₃ in a radio frequency furnace at 1000° C. for 2 hours.

The structure of the red nitride phosphor SLA has two (2) eight-coordination (which is formed by eight nitrogen atoms) and highly symmetric Sr²⁺ lattice point positions. In the case that the coordination number is eight (8), the ionic radius of Sr²⁺ is about 1.26 Å and the ionic radius of Eu²⁺ is about 1.25 Å, such that Eu²⁺ could easily enter the Sr²⁺ lattice point positions to replace Sr²⁺. Furthermore, since the coordination environment for the activator Eu²⁺ is highly symmetric, the emission spectrum of the red nitride phosphor SLA could have a narrower full width at half maximum and a better luminous efficacy that is 14% higher than that of the phosphor CaAlSiN₃:Eu²⁺. However, the performance of the red nitride phosphor SLA is still insufficient to fulfill the demands of current displays with high brightness and wide color gamut area in terms of luminous efficacy and luminous efficiency. Therefore, there is still a need for phosphors with excellent luminous efficacy and luminous efficiency.

### SUMMARY OF THE INVENTION

In view of the aforementioned technical problems, the present invention provides a red nitride phosphor, wherein the emission spectral position of the red nitride phosphor can be shifted by doping Ga³⁺ into SrLiAl₃N₄:Eu²⁺ and controlling the ratio of Ga³⁺ and Al³⁺. As a result, the emission spectral position of the red nitride phosphor can be adjusted by changing the ratio of constituents and thereby the luminous efficacy and luminous efficiency can be improved.

Therefore, an objective of the present invention is to provide a red nitride phosphor, which is represented by the following general formula (I):

SrLi(GaₓAl₁₋ₓ)₃N₄:Eu²⁺ general formula (I),

in general formula (I), 0<x≤1.

In some embodiments of the present invention, the red nitride phosphor is represented by the following general formula (II):

Sr_{1-y}Li(GaₓAl₁₋ₓ)₃N₄:yEu²⁺ general formula (II),

in general formula (II), 0<x≤1 and 0<y≤0.2, or particularly, 0.01<y≤0.05.

In some embodiments of the present invention, in general formulas (I) and (II), 0.033≤x≤0.7.

In some embodiments of the present invention, the red nitride phosphor has an emission wavelength ranging from 610 nm to 660 nm when the red nitride phosphor is excited by light with a wavelength ranging from 400 nm to 550 nm.

Another objective of the present invention is to provide a light-emitting device, which comprises:

a light source which emits light with a wavelength ranging from 400 nm to 550 nm; and
a phosphor layer, comprising the aforementioned red nitride phosphor, and being disposed such that the red nitride phosphor can be excited by the light emitted by the light source.

In some embodiments of the present invention, the light-emitting device is a light-emitting diode.

To render the above objectives, the technical features and advantages of the present invention more apparent, the present invention will be described in detail with reference to some embodiments hereinafter.

### BRIEF DESCRIPTION OF THE DRAWINGS

FIG. 1 shows the X-ray powder diffraction patterns of Sr_{0.98}Li(GaₓAl₁₋ₓ)₃N₄:0.02Eu²⁺ under different x values, wherein Sr_{0.98}Li(GaₓAl₁₋ₓ)₃N₄:0.02Eu²⁺ is one embodiment of the red nitride phosphor of the present invention, and x is 0, 0.033, 0.067, 0.1, 0.2, 0.3, 0.4. 0.5, and 0.6.

FIG. 2 shows the variation of unit lattice versus x values of Sr_{0.98}Li(GaₓAl₁₋ₓ)₃N₄:0.02Eu²⁺, which is one embodiment of the red nitride phosphor of the present invention, wherein x is 0, 0.033, 0.067, 0.1, 0.2, 0.3, 0.4. 0.5, and 0.6.

FIG. 3 shows the excitation spectra (left chart) and emission spectra (right chart) of Sr_{0.98}Li(GaₓAl₁₋ₓ)₃N₄:0.02Eu²⁺ under different x values, wherein Sr_{0.98}Li(GaₓAl₁₋ₓ)₃N₄:0.02Eu²⁺ is one embodiment of the red nitride phosphor of the present invention, and x is 0, 0.033, 0.067, 0.1, 0.2, 0.3, 0.4. 0.5, and 0.6.

FIG. 4 shows the normalized emission spectra of Sr_{0.98}Li(GaₓAl₁₋ₓ)₃N₄:0.02Eu²⁺ under different x values, wherein Sr_{0.98}Li(GaₓAl₁₋ₓ)₃N₄:0.02Eu²⁺ is one embodiment of the red nitride phosphor of the present invention, and x is 0, 0.033, 0.067, 0.1, 0.2, 0.3, 0.4. 0.5, and 0.6.

FIG. 5 shows the variation of emission wavelength and luminous intensity versus x values of Sr_{0.98}Li(GaₓAl₁₋ₓ)₃N₄:0.02Eu²⁺, which is one embodiment of the red nitride phosphor of the present invention, wherein x is 0, 0.033, 0.067, 0.1, 0.2, 0.3, 0.4. 0.5, and 0.6.

FIG. 6 shows the variation of luminous efficacy versus x values of Sr_{0.98}Li(GaₓAl₁₋ₓ)₃N₄:0.02Eu²⁺, which is one embodiment of the red nitride phosphor of the present invention, wherein x is 0, 0.033, 0.067, 0.1, 0.2, 0.3, 0.4. 0.5, and 0.6.

### DESCRIPTION OF THE PREFERRED EMBODIMENT

Hereinafter, some embodiments of the present invention will be described in detail. However, without departing from the spirit of the present invention, the present invention may be embodied in various embodiments and should not be limited to the embodiments described in the specification.

Unless it is additionally explained, the expressions “a,”, “an”, “the,” or the like recited in the specification (especially in the claims) should include both the singular and the plural forms.

As used herein, the term “about” refers that the designated amount may increase or decrease a magnitude that is general and reasonable to persons skilled in the art.

The inventive efficacy of the present invention lies in that, Ga³⁺ is doped into a nitride phosphor to provide a nitride phosphor with a general formula SrLi(GaₓAl₁₋ₓ)₃N₄:Eu²⁺, and as a result, the emission spectral position of the nitride phosphor can be shifted and the luminous efficacy and luminous efficiency can be improved. The descriptions for the composition and preparation method of the red nitride phosphor of the present invention are provided below.

The red nitride phosphor of the present invention is represented by the following general formula (I):

SrLi(GaₓAl₁₋ₓ)₃N₄:Eu²⁺ general formula (I).

In general formula (I), 0<x≤1. In terms of the balance between the emission spectral position and luminous intensity, x preferably ranges from 0.033 to 0.7. For example, x can be 0.035, 0.04, 0.045, 0.05, 0.055, 0.06, 0.067, 0.07, 0.075, 0.08, 0.085, 0.09, 0.095, 0.1, 0.133, 0.15, 0.2, 0.25, 0.3, 0.33, 0.4, 0.45, 0.5, 0.55, 0.6, 0.63, or 0.67, but the present invention is not limited thereto. In the appended Examples, x is 0.033, 0.067, 0.1, 0.2, 0.3, 0.4, 0.5, or 0.6.

In general formula (I), Eu²⁺ is an activator. The amount of the activator Eu²⁺ is not particularly limited but can be adjusted depending on the need of persons having ordinary skill in the art. In some embodiments of the present invention, the red nitride phosphor of the present invention can be represented by the following general formula (II):

Sr_{1-y}Li(GaₓAl₁₋ₓ)₃N₄:yEu²⁺ general formula (II).

In general formula (II), the definition of x is identical to that in general formula (I), and 0<y≤1, more specifically, 0.01≤y≤0.05. For example, y can be 0.015, 0.02, 0.025, 0.03, 0.035, 0.04, or 0.045. In the appended Examples, y is 0.02.

The red nitride phosphor of the present invention at least can be excited by light with a wavelength ranging from 400 nm to 550 nm to radiate light with an emission wavelength ranging from 610 nm to 660 nm, such as 612 nm, 615 nm, 620 nm, 623 nm, 625 nm, 627 nm, 630 nm, 632 nm, 635 nm, 637 nm, 640 nm, 642 nm, 645 nm, 648 nm, 650 nm, 652 nm, 655 nm, 656 nm, or 657 nm. The higher the amount of Ga³⁺ in the red nitride phosphor SrLi(GaₓAl₁₋ₓ)₃N₄:Eu²⁺, the shorter the emission wavelength. As used herein, the emission wavelength refers to the peak wavelength.

In addition, the red nitride phosphor of the present invention has a narrow full width at half maximum in the emission spectrum, which is only about 50 nm to about 60 nm, and more specifically about 52 nm to about 59 nm, such as 53 nm, 54 nm, 55 nm, 56 nm, 57 nm, or 58 nm. By comparison with conventional red nitride phosphors which have wider emission spectra with a portion of the emission spectral position falling outside the sensitive area of human eyes, the red nitride phosphor of the present invention shows better luminous efficiency and luminous efficacy.

The method for preparing the red nitride phosphor of the present invention is not particularly limited. The red nitride phosphor of the present invention can be prepared by any conventional methods for preparing nitride phosphors. Examples of the conventional methods include solid-state reaction method, co-precipitation method, spray pyrolysis method, and sol-gel method, but the present invention is not limited thereto. In some embodiments of the present invention, the red nitride phosphor of the present invention is prepared by using solid-state high-pressure pressing method, wherein the precursor of the red nitride phosphor is pressed through hot isostatic press (HIP). The precursor of the red nitride phosphor includes one or more metal nitrides which include the metal elements composing the red nitride phosphor. The composition of the precursor of the red nitride phosphor depends on the desired molar ratio of each metal elements in the red nitride phosphor. For example, when preparing the red nitride phosphor with general formula (II) Sr_{1-y}Li(GaₓAl₁₋ₓ)₃N₄:yEu²⁺, the precursor of the red nitride phosphor may include strontium nitride, lithium nitride, aluminum nitride, gallium nitride, and europium nitride, and the amounts of strontium nitride, lithium nitride, aluminum nitride, gallium nitride, and europium nitride should be determined such that the molar ratio of Sr:Li:Ga:Al:Eu is (1-y):1:3x:3(1-x):y, wherein 0<x≤1 and 0<y≤0.2. The solid-state high-pressure pressing method can be performed in an inert atmosphere at a temperature ranging from about 800° C. to about 1500° C., preferably about 900° C. to about 1100° C., and a pressure ranging from about 10 MPa to about 200 MPa, preferably about 50 MPa to about 150 MPa. In the appended Examples, the solid-state high-pressure pressing method is performed in a nitrogen atmosphere at a temperature of 1000° C. and a pressure of 100 MPa.

The red nitride phosphor of the present invention can be excited by light with a specific wavelength and radiates red light. Therefore, the present invention also provides a light-emitting device, such as a light-emitting diode, which comprises a light source capable of emitting light with a wavelength ranging from 400 nm to 550 nm and a phosphor layer. The phosphor layer comprises the red nitride phosphor of the present invention and is disposed such that the red nitride phosphor can be excited by the light emitted by the light source.

In the light-emitting device of the present invention, the light source preferably emits light with a wavelength ranging from 420 nm to 520 nm in order to effectively excite the red nitride phosphor of the present invention. Examples of the light source include but are not limited to semiconductor light-emitting elements which emit blue light or green light. Examples of the semiconductor light-emitting elements include but are not limited to GaN-based light-emitting elements, InGaN-based light-emitting elements, InAlGaN light-emitting elements, SiC light-emitting elements, ZnSe light-emitting elements, BN light-emitting elements, and BAlGaN light-emitting elements.

In the light-emitting device of the present invention, the phosphor layer can be formed by coating a composition comprising the red nitride phosphor onto the outer surface of the light source. Alternatively, the phosphor layer can be formed into a separate member and disposed in the travelling path of the light emitted by the light source. Furthermore, the phosphor layer may further comprise one or more phosphors other than the red nitride phosphor of the present invention to obtain desired luminous performance. For example, in the case of using a blue-light semiconductor light-emitting element as the light source, the phosphor layer can further comprise phosphors with different colors, such as a yellow phosphor, a green phosphor, and the like, to provide a white-light light-emitting device.

The present invention will be further illustrated by the embodiments hereinafter.

### EXAMPLES

### 1. Preparation of Red Nitride Phosphor Sr_{1-y}Li(GaₓAl₁₋ₓ)₃N₄:yEu²⁺

### Example 1

The raw materials including Sr₃N₂, Li₃N, AlN, GaN and EuN were weighed at a stoichiometry ratio and ground in an agate mortar, wherein the weighing and grinding processes were performed in a glove box filled with argon (5N purity) under a moisture and oxygen concentration lower than 1 ppm. After the raw materials were evenly mixed, the mixture was placed in a boron nitride mortar, and then the boron nitride mortar was placed in a hot isostatic pressing furnace to conduct the pressing under the following conditions: in a pressing atmosphere of argon (5N purity), the hot isostatic pressing furnace was heated to 1000° C. with a heating rate of 10° C./min to conduct the pressing at 1000° C. and 100 MPa for four (4) hours, and then the hot isostatic pressing furnace was cooled to room temperature with a cooling rate of 20° C./min. The red nitride phosphor Sr_{1-y}Li(GaₓAl₁₋ₓ)₃N₄:yEu²⁺ was obtained, wherein x is 0.033 and y is 0.02.

### Example 2

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.067.

### Example 3

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.1.

### Example 4

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.2.

### Example 5

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.3.

### Example 6

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.4.

### Example 7

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.5.

### Example 8

The preparation procedures of Example 1 were repeated to prepare the red nitride phosphor Sr_{1-y}Li(GaₓAl₁₋ₓ)₃N₄:yEu²⁺, except that the stoichiometry ratio was adjusted so that x is 0.6.

### 2. Preparation of Red Nitride Phosphor SLA

### Comparative Example 1

The raw materials including Sr₃N₂, Li₃N, AlN and EuN were weighed at a stoichiometry ratio and ground in an agate mortar, wherein the weighing and grinding processes were performed in a glove box filled with argon (5N purity) under a moisture and oxygen concentration lower than 1 ppm. After the raw materials were evenly mixed, the mixture was placed in a boron nitride mortar, and then the boron nitride mortar was placed in a hot isostatic pressing furnace to conduct the pressing under the following conditions: in a pressing atmosphere of argon (5N purity), the hot isostatic pressing furnace was heated to 1000° C. with a heating rate of 10° C./min to conduct the pressing at 1000° C. and 100 MPa for four (4) hours, and then the hot isostatic pressing furnace was cooled to room temperature with a cooling rate of 20° C./min. The red nitride phosphor SLA was obtained.

### 3. Analysis of Phosphors

The X-ray powder diffraction pattern (measured by D2 Phaser diffractometer, available from Bruker) and fluorescence emission spectrum (measured by FluoroMax-3, available from HORIBA) of each nitride phosphors prepared in Examples 1 to 8 and Comparative Example 1 were respectively analyzed. Then the unit lattice parameters were calculated from the X-ray powder diffraction pattern, and the luminous intensity, full width at half maximum and luminous efficacy were calculated from the fluorescence emission spectrum. The luminous efficacy is defined by the following equations, wherein K is the luminous efficacy, y̅(λ) refers to the sensitive curve of human eyes, Φᵥ refers to the luminous flux detectable in the sensitive curve of the human eye, Φₑ is the radiation power of the light source, Φ_{e,λ} is the fluorescence emission spectra of each nitride phosphors, and λ is the emission wavelength of each nitride phosphors.

$$K = \frac{{Φ}_{v}}{{Φ}_{e}} = \frac{{\int }_{0}^{∞} K ( λ ) {Φ}_{e , λ} d λ}{{\int }_{0}^{∞} {Φ}_{e , λ} d λ}$$

$${Φ}_{v} = 683.002 lm \text{/} W \cdot {\int }_{0}^{∞} \overline{y} ( λ ) {Φ}_{e , λ} d λ$$

$$\overline{y} ( λ ) = 1.019 {e}^{- 282.4} \text{?}$$

$$\text{?} \text{indicates text missing or illegible when filed}$$

The definition of the above equations for luminous efficacy may refer to Tannous, C. “Light Production Metrics of Radiation Sources.” Eur. J. Phys. 2014, 35, 045006, and the subject matters of which are incorporated herein in their entirety by reference.

The analysis results of the phosphors prepared in Examples 1 to 8 and Comparative Example 1 are described below.

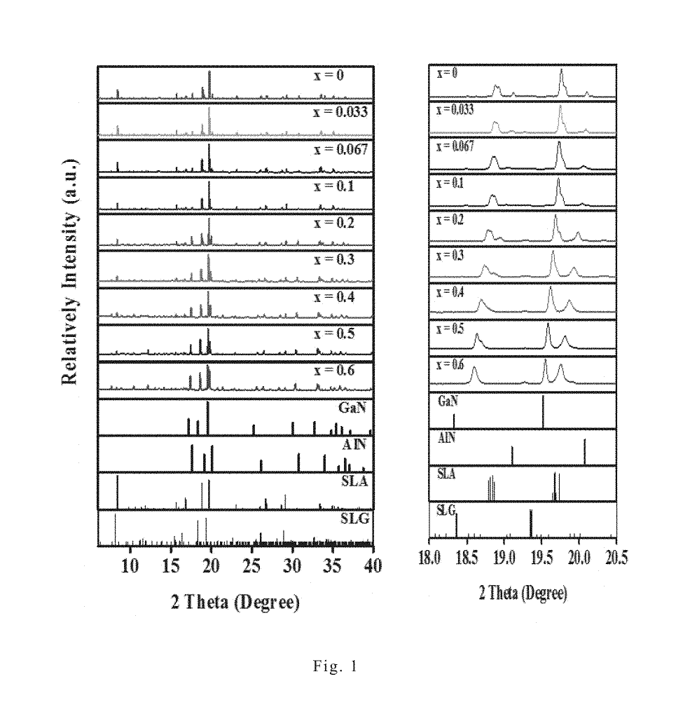

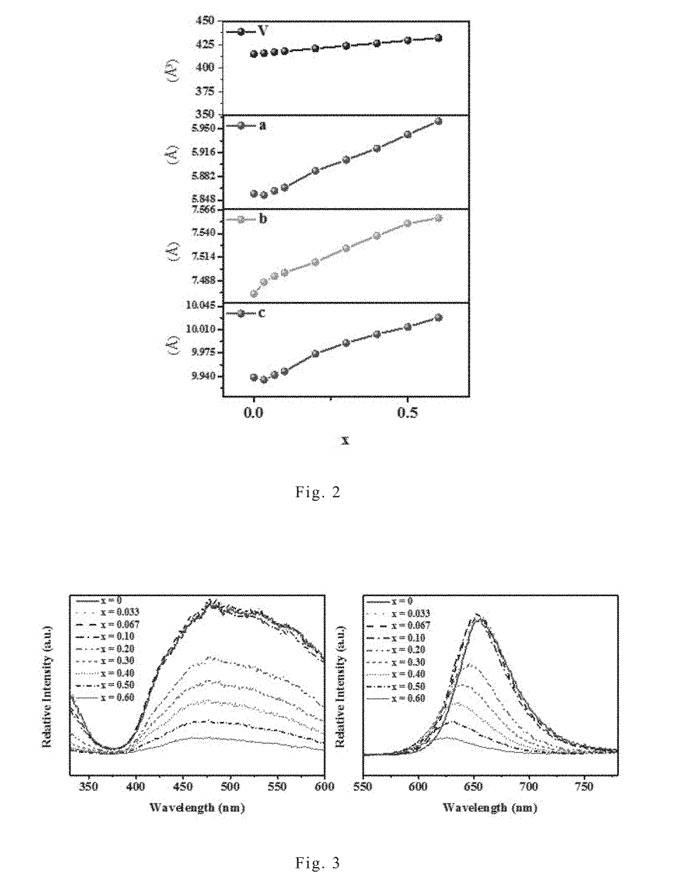

FIG. 1 shows the X-ray powder diffraction patterns of the red nitride phosphor Sr_{0.98}Li(GaₓAl₁₋ₓ)₃N₄:0.02Eu²⁺ of the present invention under different x values, wherein x is 0, 0.033, 0.067, 0.1, 0.2, 0.3, 0.4. 0.5, and 0.6. In FIG. 1, SLG refers to the red nitride phosphor with x=1, and GaN, AlN and SLA are standard patterns published by Joint Committee on Powder Diffraction Standard (JCPDS). As shown in FIG. 1, by comparison with the standard patterns from JCPDS, it was found that those nitride phosphors all have triclinic structure, and the position of main diffraction peak shifts to a smaller degree along with the increase of x. The unit lattice parameters of those nitride phosphors were calculated from the X-ray powder diffraction patterns and the result is shown in FIG. 2.

FIG. 2 shows the variation of unit lattice versus x values of the red nitride phosphor Sr_{0.98}Li(GaₓAl₁₋ₓ)₃N₄:0.02Eu²⁺ of the present invention, wherein x is 0, 0.033, 0.067, 0.1, 0.2, 0.3, 0.4. 0.5, and 0.6. As shown in FIG. 2, it was found that the unit lattice parameters of the nitride phosphors increased along with the increase of x. This demonstrates that the doping of Ga³⁺ changes the host lattice structure.

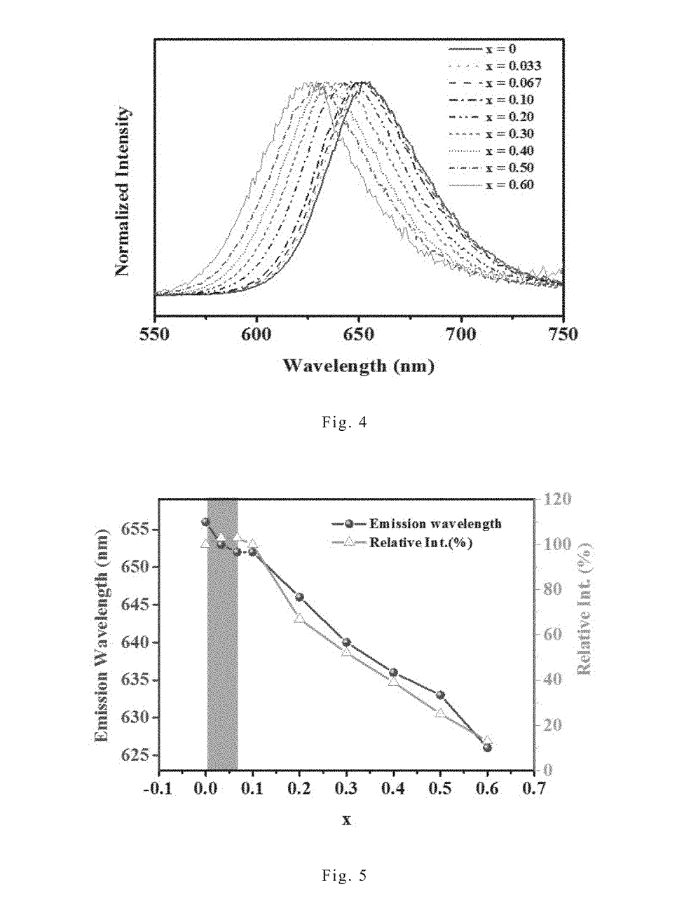

FIG. 3 shows the excitation spectra (left chart) and emission spectra (right chart) of the red nitride phosphor Sr_{0.98}Li(GaₓAl₁₋ₓ)₃N₄:0.02Eu²⁺ of the present invention under different x values, wherein x is 0, 0.033, 0.067, 0.1, 0.2, 0.3, 0.4. 0.5, and 0.6. FIG. 4 shows the normalized emission spectra of the red nitride phosphor Sr_{0.98}Li(GaₓAl₁₋ₓ)₃N₄:0.02Eu²⁺ of the present invention under different x values, wherein x is 0, 0.033, 0.067, 0.1, 0.2, 0.3, 0.4. 0.5, and 0.6. FIG. 4 normalizes the emission spectra of FIG. 3 in order to more clearly show the variation of the emission spectral positions of each red nitride phosphors. As shown in FIG. 3, all those red nitride phosphors can be excited by light with a wavelength ranging from 400 nm to 550 nm, therefore all those red nitride phosphors can be excited by a blue-light light-emitting diode or a green-light light-emitting diode. Furthermore, as shown in FIGS. 3 and 4, red nitride phosphor SLA (i.e., the embodiment in which x is 0) has an emission wavelength of about 656 nm. The red nitride phosphor of the present invention has a shorter emission wavelength compared to red nitride phosphor SLA; and the higher the Ga³⁺ amount (i.e., the higher the x value), the shorter the emission wavelength. In the case of x=0.6, the emission wavelength of the red nitride phosphor can be shortened to about 626 nm, making the light emitted by the red nitride phosphor of the present invention more detectable to human eyes. In addition, the emission spectrum of the red nitride phosphor of the present invention has a narrow full width at half maximum, which only ranges from 56 nm to about 59 nm.

FIG. 5 shows the variation of emission wavelength and luminous intensity versus x values of the red nitride phosphor Sr_{0.98}Li(GaₓAl₁₋ₓ)₃N₄:0.02Eu²⁺ of the present invention, wherein x is 0, 0.033, 0.067, 0.1, 0.2, 0.3, 0.4. 0.5, and 0.6. As shown in FIG. 5, in the case of 0<x≤0.067, it was found that the emission wavelength is shortened along with the increase of x, while the luminous intensity enhances along with the increase of x. In the case that x is higher than 0.067, it was found that the emission wavelength is further shortened along with the increase of x.

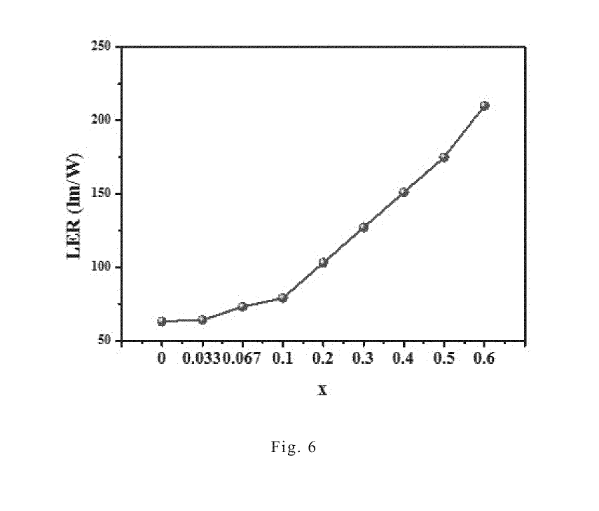

FIG. 6 shows the variation of luminous efficacy versus x values of the red nitride phosphor Sr_{0.98}Li(GaₓAl₁₋ₓ)₃N₄:0.02Eu²⁺ of the present invention, wherein x is 0, 0.033, 0.067, 0.1, 0.2, 0.3, 0.4. 0.5, and 0.6. In FIG. 6, luminous efficacy is represented by LER (Luminous Efficacy of Radiation), and the unit thereof is lm/Wₒₚₜ. As shown in FIG. 6, the luminous efficacy of the red nitride phosphor significantly enhances along with the increase of x. When x is 0.6, the red nitride phosphor Sr_{0.98}Li(GaₓAl₁₋ₓ)₃N₄:0.02Eu²⁺ has luminous efficacy up to about 200 lm/Wₒₚₜ, which is 8 times higher than the luminous efficacy of the red nitride phosphor SLA.

The above analysis results manifest that, by comparison with conventional red nitride phosphors, the red nitride phosphor of the present invention has an emission spectral position which can be shifted to short wavelength direction and thus to facilitate the detection of human eyes and has excellent luminous efficacy and luminous efficiency.

The above examples are used to illustrate the principle and efficacy of the present invention and show the inventive features thereof. People skilled in this field may proceed with a variety of modifications and replacements based on the disclosures and suggestions of the invention as described without departing from the principle and spirit thereof. Therefore, the scope of protection of the present invention is that as defined in the claims as appended.

What is claimed is:

1. A red nitride phosphor, which is represented by the following general formula (I):
SrLi(GaₓAl₁₋ₓ)₃N₄:Eu²⁺ general formula (I),
in general formula (I), 0<x≤1.

2. The red nitride phosphor of claim 1, which is represented by the following general formula (II):
Sr_{1-y}Li(GaₓAl₁₋ₓ)₃N₄:yEu²⁺ general formula (II),
in general formula (II), 0<x≤1 and 0<y≤0.2.

3. The red nitride phosphor of claim 2, wherein 0.01<y≤0.05.

4. The red nitride phosphor of claim 1, wherein in general formulas (I) and (II), 0.033≤x≤0.7.

5. The red nitride phosphor of claim 2, wherein in general formulas (I) and (II), 0.033≤x≤0.7.

6. The red nitride phosphor of claim 3, wherein in general formulas (I) and (II), 0.033<x≤0.7.

7. The red nitride phosphor of claim 1, which has an emission wavelength ranging from 610 nm to 660 nm when being excited by light with a wavelength ranging from 400 nm to 550 nm.

8. The red nitride phosphor of claim 2, which has an emission wavelength ranging from 610 nm to 660 nm when being excited by light with a wavelength ranging from 400 nm to 550 nm.

9. The red nitride phosphor of claim 3, which has an emission wavelength ranging from 610 nm to 660 nm when being excited by light with a wavelength ranging from 400 nm to 550 nm.

10. A light-emitting device, comprising:
a light source which emits light with a wavelength ranging from 400 nm to 550 nm; and
a phosphor layer, comprising the red nitride phosphor of claim 1, and being disposed such that the red nitride phosphor can be excited by the light emitted by the light source.

11. The light-emitting device of claim 10, which is a light-emitting diode.
